(19) United States
(12) Patent Application Publication
(10) Pub. No.: US 2010/0171175 A1
(43) Pub. Date: Jul. 8, 2010

(54) Structure For High Voltage/High Current MOS Circuits

(76) Inventors: Bing-Yao Fan, Hsinchu (TW); Ming-Yi Hsieh, Pingtung (TW); Tsuoe-Hsiang Liao, Hsinchu (TW); Maw-Hwa Chen, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 12/348,903

(22) Filed: Jan. 5, 2009

(51) Int. Cl. H01L 29/78

(52) U.S. Cl. 257/343; 257/E29.261

(57) ABSTRACT

A semiconductor structure for high voltage/high current MOS circuits is provided, including a deep N-well (NMD), a P-well (PW) disposed within NWD, a plurality of field oxide regions (FOX), a plurality of doping regions, including both N+ regions and P+ regions, disposed within NWD and PW, a gate (G) connected to a doping region, a bulk pad (B) connected to a doping regions, a source pad (S) connected to a doping regions and a drain pad (D) connected to a doping region. The top view of the present invention shows that the regions are of non-specific shapes and overlaid in a radial manner, with doping region connected to B being encompassed by doping region connected to S, which in turn encompassed by G, encompassed by FOX, encompassed by doping region connected to D. As long as the regions are overlaid in a manner that one region surrounds another region so that the electric current flows from S towards D in a radiating manner, the geometry and the layout of the semiconductor structure of the present invention can be varied.

### FIELD OF THE INVENTION

The present invention generally relates to a structure for high voltage MOS circuits, and more specifically to a structure for high voltage/high current MOS circuits.

### BACKGROUND OF THE INVENTION

The popularity of thin and small electronic devices powers the continuous progress in the design and manufacturing of semiconductor devices. As the demands of the semiconductor devices to operate at high voltage and high current, the challenge remains ahead for the semiconductor industry is to achieve the high output current circuit after overcoming the restriction on the high voltage.

In general, conventional structure for MOS circuits has an orthogonal-based layout; that is, the regions in the semiconductor structure, such as n-well, oxide layer, metal layer, poly layer, p+ doping area, n+ doping area, has the shape of square or rectangular, or connected rectangles and squares, and the orientation of these regions are orthogonal from the top view.

For example, FIG. 1 shows a top view with a corresponding cross-sectional view of the first embodiment of the conventional semiconductor structure of a high voltage (HV) PMOS transistor. The upper part of FIG. 1 shows the top view and the lower part shows the corresponding cross-sectional view. As shown in FIG. 1, a semiconductor structure for HV PMOS transistor includes a deep N-well (NMD) 101, a P-well (PW) 103 disposed within NWD 101, a plurality of field oxide regions (FOX) 105, a plurality of doping regions, including both N+ regions 107 and P+ regions 109, disposed within NWD 101 and PW 103, a gate (G) 111, a bulk pad (B) 113, a source pad (S) 115 and a drain pad (D) 117, where B 113 is connected to an N+ region 107, S 115 is connected to a P+ region 109 and D 117 is connected to a P+ region 109. In this embodiment, the aforementioned N+ regions 107 and P+ regions 109 are arranged with N+ region 107 connected to B 113 being disposed within NWD 101, P+ region 109 connected to S 115 being disposed within NWD 101, and P+ region 109 connected to D 117 being disposed within PW 103. It is worth noting that the cross-sectional transistor is only an illustrating exemplar, other circuits may also have the similar characteristics of the above structure.

Similarly, FIG. 2 shows a top view with a corresponding cross-sectional view of a conventional semiconductor structure of implementing HV NMOS transistor. As shown in FIG. 2, a semiconductor structure for HV NMOS transistor includes an NMD 201, a PW 203 disposed within NWD 201, a plurality of FOX 205, a plurality of doping regions, including P+ regions 207 and N+ regions 209, disposed within NWD 201 and PW 203, a gate (G) 211, a bulk pad (B) 213, a source pad (S) 215 and a drain pad (D) 217, where B 213 is connected to a P+ region 207, S 215 is connected to an N+ region 209 and D 217 is connected to an N+ region 209. In this embodiment, the aforementioned P+ regions 207 and N+ regions 209 are arranged with P+ region 207 connected to B 213 being disposed within PW 203, N+ region 209 connected to S 215 being disposed within PW 203, and N+ region 209 connected to D 117 being disposed within NWD 201. As the semiconductor structure for NMOS is similar to that of PMOS, the following description regarding the geometric characteristics of the structure and the limitation of the electrical characteristic is applicable to both PMOS and NMOS.

However, there exist several shortcomings of the conventional semiconductor structures shown in FIG. 1 and FIG. 2. FIG. 3A and FIG. 3B show the schematic views of the geometry causing the shortcomings of the conventional semiconductor structures shown in FIG. 1 and FIG. 2. As shown in FIG. 3A, the shortcoming of the regions with right angle geometry in MOS circuits is that corner of the angle, the tip of the angle in particular, will accumulate high electric charge density. When the surface electric field at the tip exceeds the threshold, an early breakdown occurs. In other words, when the electric field imposed on the dielectric material exceeds the threshold, the current flowing through the dielectric material will suddenly increase, resulting in the phenomenon of ineffective dielectric material, i.e., a sudden surge of high voltage penetrates the material to discharge. Hence, the conventional semiconductor structure is unable to be used in high current MOS circuit design.

FIG. 3B shows another shortcoming of the conventional semiconductor structure. As shown in FIG. 3B, when the width of MOS is too wide, the ion doping density may not be uniform in the manufacturing process, which will lead to the electric current distribution later on. This will also complicate the above early breakdown shortcoming depicted in FIG. 3A.

Some alternative designs have been proposed to improve the conventional semiconductor structure. For example, FIG. 4 shows a rounded-corner design is proposed to replace the right angle design, of the regions in the semiconductor structure. The column area of the rounded-corner geometry shown in FIG. 4 has a higher electric field than the parallel electric field, and with a smaller breakdown voltage. Furthermore, the rounded-corner will have an even higher electric field than the column area, with an even smaller breakdown voltage.

While the alternative design may improve the shortcomings in the conventional structure, the intrinsic shortcomings from the geometry and the orthogonal layout of the conventional structure remain a challenge to the provision of high voltage/high current MOS circuits. It is imperative to devise a novel semiconductor structure to overcome the restriction and enable the development of high voltage/high current MOS circuits for a wider range of applications.

### SUMMARY OF THE INVENTION

The present invention has been made to overcome the aforementioned shortcomings of the conventional semiconductor structure for MOS circuits.

An exemplary embodiment of the present invention provides a semiconductor structure for realizing high voltage/high current (HV/HC) PMOS circuits, wherein the geometry and the overlapping layout of the regions in semiconductor structure, coupled with the placement of pads, can overcome the restrictions imposed by conventional semiconductor structure in implementing high voltage/high current PMOS circuits.

Another exemplary embodiment of the present invention provides a semiconductor structure for realizing high voltage/high current (HV/HC) NMOS circuits, wherein the geometry and the overlapping layout of the regions in semiconductor structure, coupled with the placement of pads, can overcome the restrictions imposed by conventional semiconductor structure in implementing high voltage/high current NMOS circuits.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a top view with a corresponding cross-sectional view of a conventional semiconductor structure of implementing HV PMOS transistor;

FIG. 2 shows a top view with a corresponding cross-sectional view of a conventional semiconductor structure of implementing HV NMOS transistor;

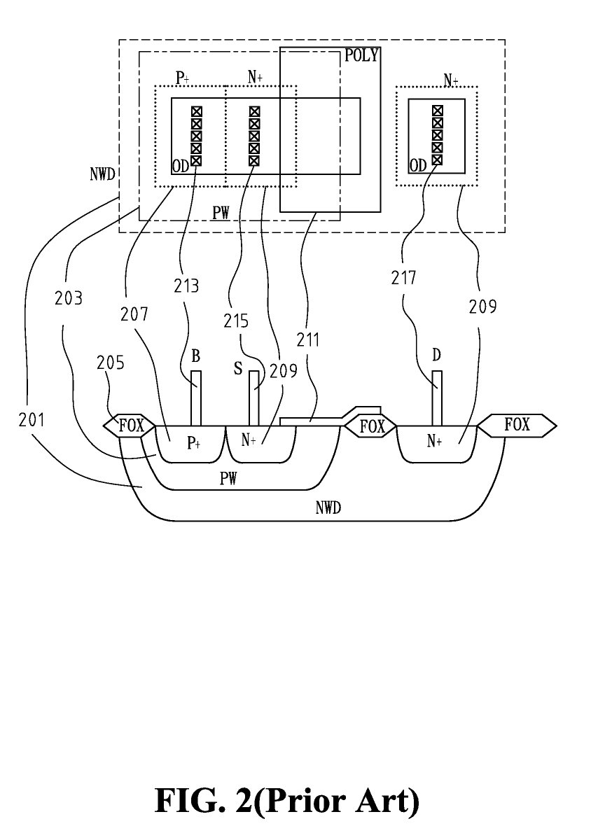

FIGS. 3A & 3B show the schematic views of the geometry causing the shortcomings of the conventional semiconductor structures shown in FIG. 1 and FIG. 2;

FIG. 4 shows a schematic view of a rounded-corner design proposed to replace the right angle design, of the regions in the conventional semiconductor structure;

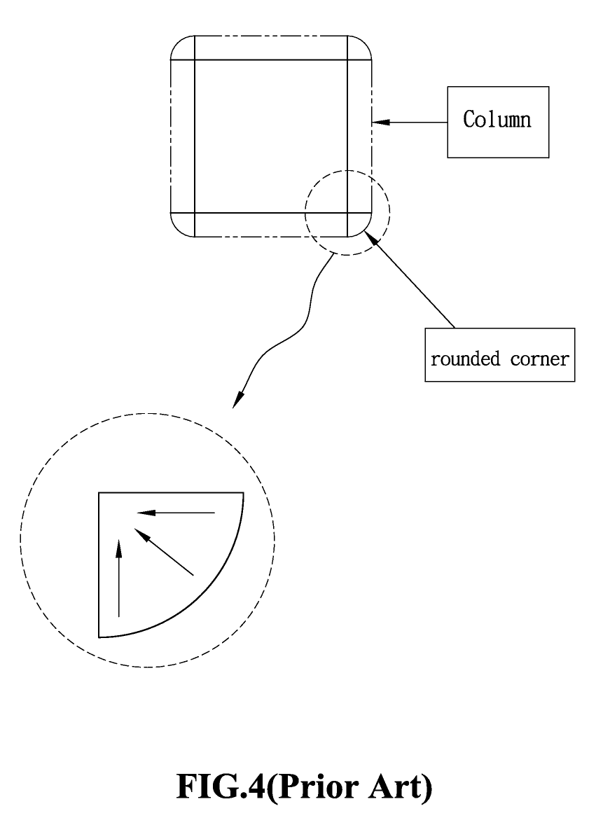

FIG. 5 shows a top view with a corresponding cross-sectional view of the first embodiment of the semiconductor structure for implementing HV/HC PMOS circuits according to the present invention;

FIG. 6 shows a top view with a corresponding cross-sectional view of the second embodiment of the semiconductor structure for implementing HV/HC NMOS circuits according to the present invention; and

FIG. 7A & FIG. 7B show the schematic views of the advantages of the semiconductor structure of the present invention.

### DETAILED DESCRIPTION OF THE PREFERRED EMBODIMENTS

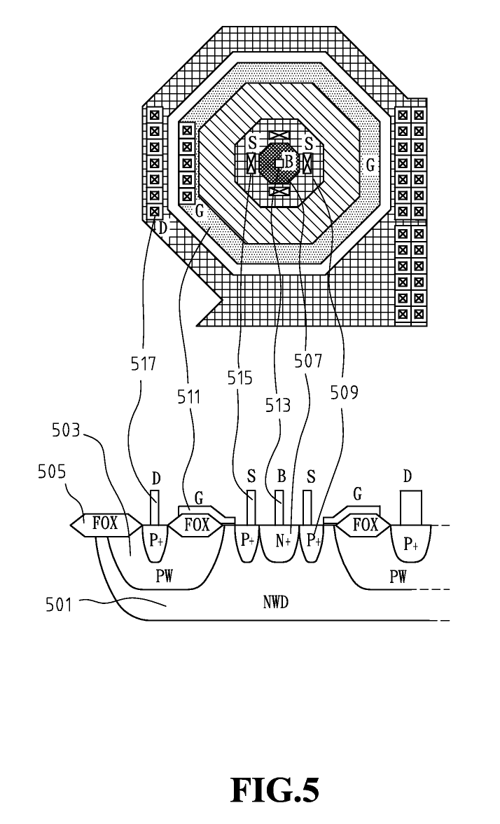

FIG. 5 shows a top view with a corresponding cross-sectional view of the first embodiment of the semiconductor structure for implementing HV/HC PMOS circuits according to the present invention. The upper part of FIG. 5 shows the top view and the lower part shows the corresponding cross-sectional view crossing the bulk pad (B). It is worth noting that the cross-sectional view is on the plane containing bulk pad B, as B is about at the geometry center of the top view.

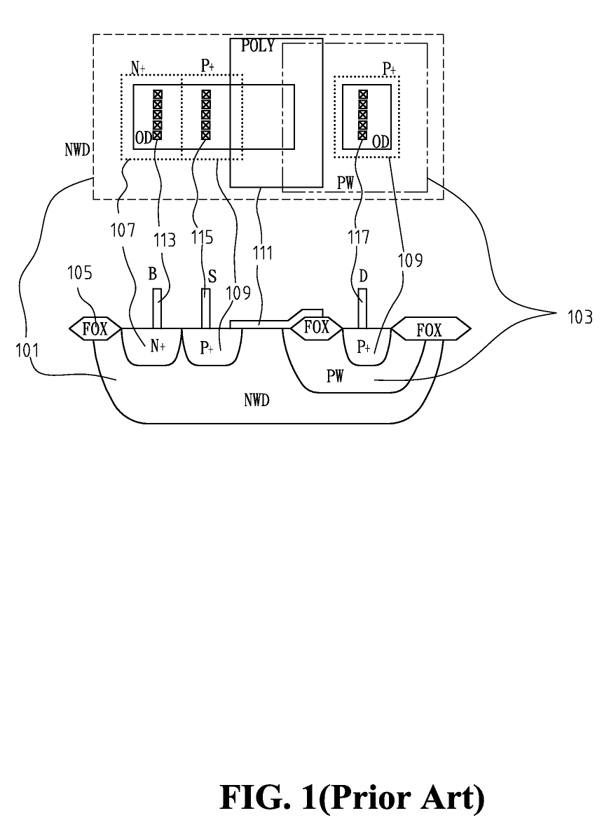

As shown in FIG. 5, the semiconductor structure of the present invention includes a deep N-well (NMD) 501, a P-well (PW) 503 disposed within NWD 101, a plurality of field oxide regions (FOX) 505, a plurality of doping regions, including both N+ regions 507 and P+ regions 509, disposed within NWD 501 and PW 503, a gate (G) 511, a bulk pad (B) 513, a source pad (S) 515 and a drain pad (D) 517, where B 513 is connected to an N+ region 507, S 515 is connected to a P+ region 509 and D 517 is connected to a P+ region 509. In addition, S 515 is arranged in a manner to surround B 513. In this embodiment, the aforementioned N+ regions 507 and P+ regions 509 are arranged with N+ region 507 connected to B 513 being disposed within NWD 501, P+ region 509 connected to S 515 being disposed within NWD 501, and P+ region 509 connected to D 517 being disposed within PW 503. However, while the cross-sectional view of the present invention may be similar to the cross-sectional view of the conventional structure in FIG. 1, the top view of the present invention is very different from the top view of the conventional structure in FIG. 1.

In comparison, the top view of the present invention shows that the regions, including NWD 501, PW 503, FOX 505, N+ regions 507 and P+ regions 509, are all in the shape of octagons and overlaid in a radial manner, with N+ region 507 connected to B 513 being encompassed by P+ region 509 connected to S 515, which in turn encompassed by said G 511, encompassed by said FOX 503, encompassed by said P+ region connected to D517. It is also worth noting that the octagonal shape is only for illustrative purpose, not for limiting the scope of the present invention. The regions in the semiconductor structure of the present invention are not limited to any specific shape, and the regions do not have to have the same shape, either. Furthermore, the shape of the regions is not necessary to be symmetric. As long as the regions are overlaid in a manner that one region surrounds another region so that the electric current flows from source pad S 515 towards drain pad D 517 in a radiating manner, the geometry and the layout of the semiconductor structure of the present invention can be varied.

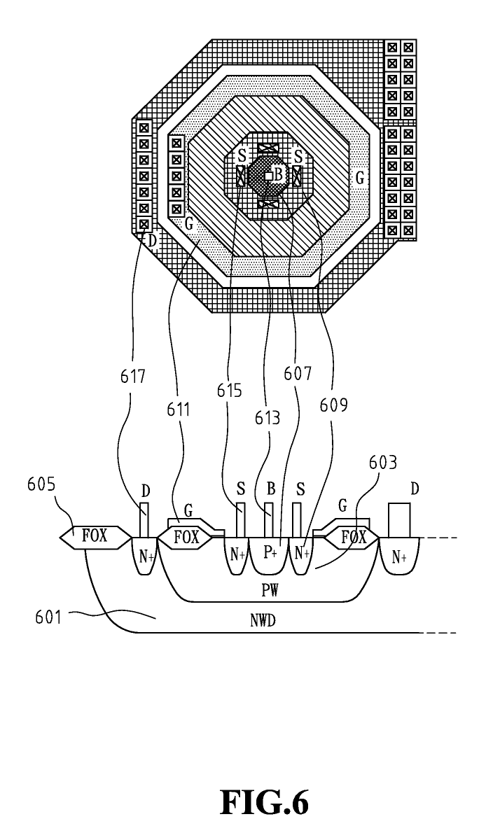

Similarly, FIG. 6 shows a top view with a corresponding cross-sectional view of the second embodiment of the semiconductor structure for implementing HV/HC NMOS circuits according to the present invention. The upper part of FIG. 6 shows the top view and the lower part shows the corresponding cross-sectional view crossing the bulk pad (B).

As shown in FIG. 6, the semiconductor structure of the present invention includes a deep N-well (NMD) 601, a P-well (PW) 603 disposed within NWD 601, a plurality of field oxide regions (FOX) 605, a plurality of doping regions, including P+ regions 607 and N+ regions 609, disposed within NWD 601 and PW 603, a gate (G) 611, a bulk pad (B) 613, a source pad (S) 615 and a drain pad (D) 617, where B 613 is connected to a P+ region 607, S 615 is connected to an N+ region 609 and D 617 is connected to an N+ region 609. The description of the exemplary embodiment in FIG. 6 is similar to that of the exemplary embodiment in FIG. 5, and thus is omitted here. The following analysis of the advantage of the present invention is applicable to both the embodiments in FIG. 5 and FIG. 6.

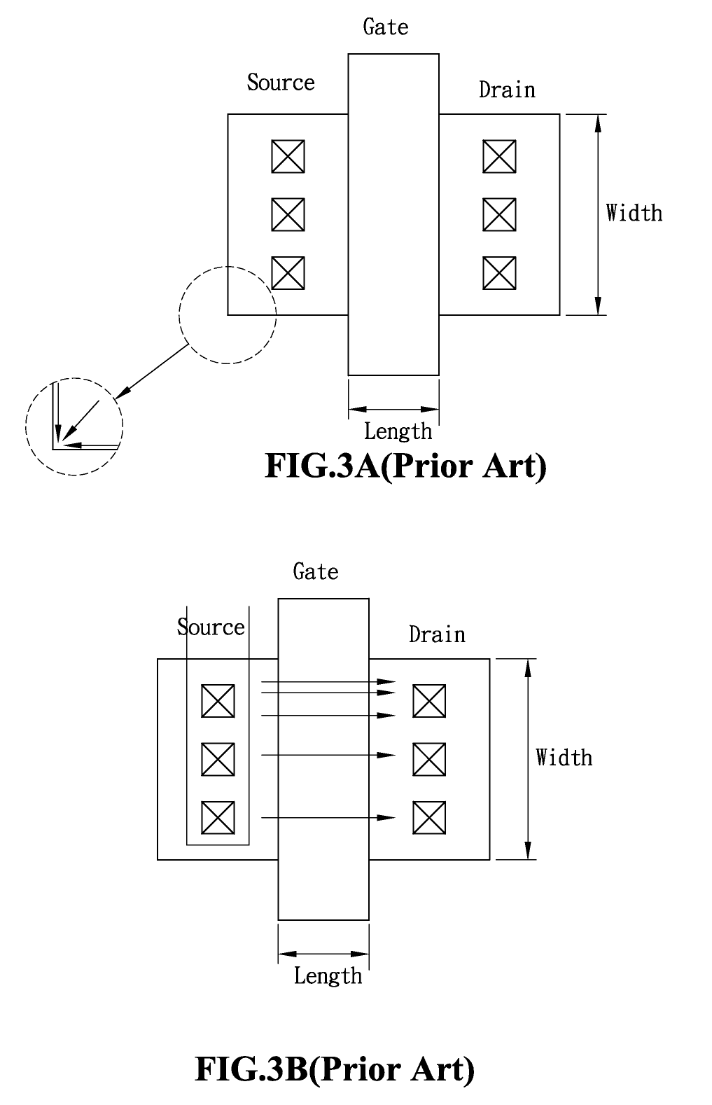

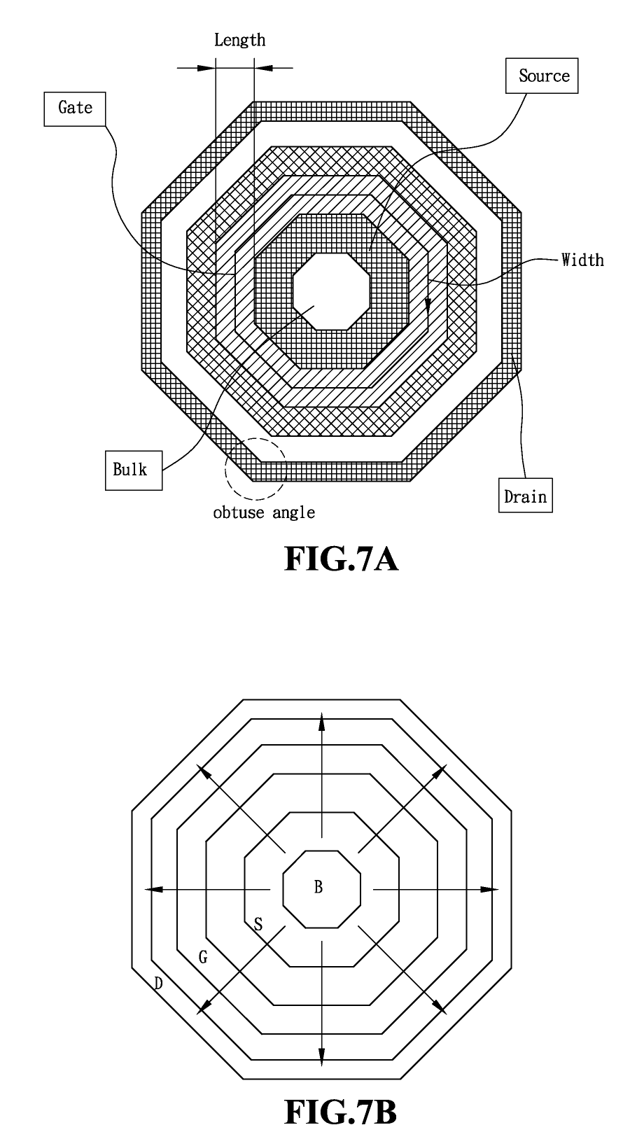

FIG. 7A and FIG. 7B show the schematic views of the advantages of the semiconductor structure of the present invention. Refer to the restrictions and the shortcomings imposed by the convention semiconductor structures of FIG. 3A and FIG. 3B. The octagonal shape of the regions of the semiconductor structure of FIG. 7A, P+ regions or N+ regions in particular, will have obtuse angles instead of the right angles of the square or rectangular shape of the regions in the conventional semiconductor structure of FIG. 3A. The obtuse angle avoids the problem caused by the breakdown and discharge at the tip of acute or right angles in the conventional semiconductor structure. It is worth noting that the large the angle is, the better the effect is. Thus, any polygonal shape without any acute or right angles or curvy shape without acute curvature can be used in the present invention.

FIG. 7B shows a schematic view of the uniform electric current distribution of the semiconductor structure of the present invention. Compared to FIG. 3B, the electric current distribution in FIG. 7B is uniform, and the electric current flows uniformly from source pad towards the drain pad in a radiating manner. The uniform electric current distribution will incur a higher electric current density to enable the implementation of HV/HC MOS circuits. In addition, the octagonal geometry and radial layout of the regions can achieve a larger width in a unit area in comparison with the square or rectangle regions. In FIG. 7A, the width is the total length of the segments forming the indicated octagon.

In summary, the semiconductor structure of the present invention has the following advantages in comparison with the conventional semiconductor structure:
1. The elimination of acute or right angles can avoid the breakdown and discharge at the tip of the acute or right angles.
2. The higher width of the transistor geometry can be obtained in a unit area.
3. The electric current distribution is more uniform and the overall electric current density is increased, which enables the implementation of HV/HC MOS circuits.
4. The semiconductor structure improves the overall layout of the circuit and increase the overall effective utilization of the semiconductor area.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A semiconductor structure for implementing high voltage/high current MOS circuits, comprising:
a deep N-well (NWD);
a P-well (PW), disposed within said NWD;
a plurality of doping regions, disposed within said NWD and said PW, said doing regions further comprising N+ regions and P+ regions;
a plurality of field oxide (FOX);
a bulk (B) pad, connected to a said doping region;
a source (S) pad, connected to a said doping region;
a (D) drain pad, connected to a said doping region; and
a gate (G), located between said S pad and said D pad;
wherein the top view of said semiconductor structure being said NWD, said PW, said doping regions and said FOX of non-specific shape overlaid in a radial manner, and said doping region connected to said B pad being encompassed by said doping region connected to said S pad, which in turn encompassed by said G, encompassed by said FOX, encompassed by said doping region connected to said D pad, so that the electric current flowing from said S pad towards said D pad in a radiating manner.

2. The semiconductor structure as claimed in claim 1, wherein in PMOS circuits, said B pad is connected to an N+ regions, said S pad and D pad are both connected to a said P+ region, said B pad and said S pad are both disposed within said NWD and said D pad is disposed within said PW.

3. The semiconductor structure as claimed in claim 1, wherein in NMOS circuits, said B pad is connected to an P+ regions, said S pad and D pad are both connected to a said N+ region, said B pad and said S pad are both disposed within said PW and said D pad is disposed within said NWD.

4. The semiconductor structure as claimed in claim 1, wherein said regions of said NWD, said PW, said doping regions and said FOX are of the same shape.

5. The semiconductor structure as claimed in claim 4, wherein said shape is polygonal with only obtuse angles, or curvy shape with only appropriate curvature, or any combination of the above.

6. The semiconductor structure as claimed in claim 1, wherein said regions of said NWD, said PW, said doping regions and said FOX are of different shapes.

7. The semiconductor structure as claimed in claim 6, wherein said shapes are either polygonal with only obtuse angles, or curvy shape with only appropriate curvature, or any combination of the above.

8. A semiconductor structure for implementing high voltage/high current MOS circuits, comprising: a bulk area, a source area, a gate area, and a drain area;
wherein top view of said semiconductor structure having said bulk area located at center, surrounded by said source area, said source area surrounded by said gate area, and said gate area surrounded by said drain area.
